(19) United States
(12) Patent Application Publication
(10) Pub. No.: US 2013/0313006 A1
(43) Pub. Date: Nov. 28, 2013

(54) TOUCH PANEL AND PRODUCING METHOD OF THE SAME

(71) Applicant: Research & Business Foundation Sungkyunkwan University, (US)

(72) Inventor: Jong-Hyun AHN, Suwon-si (KR)

(73) Assignee: Research & Business Foundation Sungkyunkwan University, Suwon-si (KR)

(21) Appl. No.: 13/871,010

(22) Filed: Apr. 26, 2013

(30) Foreign Application Priority Data
May 23, 2012 (KR) 10-2012-0054563

(51) Int. Cl. H05K 1/09; H05K 3/10

(52) U.S. Cl. CPC H05K 1/097; H05K 3/10
USPC 174/257; 216/18; 430/315

(57) ABSTRACT

The present disclosure relates to a touch panel and a producing method of the same.

### CROSS-REFERENCE TO RELATED APPLICATION

This application claims the benefit of Korean Patent Application No. 10-2012-0054563 filed on May 23, 2012, the disclosures of which are incorporated herein by reference.

### FIELD OF THE INVENTION

The present disclosure relates to a touch panel and a producing method of the same.

### BACKGROUND OF THE INVENTION

Recently, an ITO (Indium Tin Oxide) transparent electrode is widely used as an essential component for use in various devices such as a touch panel, a solar cell, an indicating element, and so forth.

The ITO transparent electrode is manufactured by depositing a metal oxide such as ITO on a glass or plastic substrate by, e.g., a sputtering method. The ITO transparent electrode has high electric conductivity and transparency. However, due to an intrinsic mechanical defect and necessity to perform a high-temperature process, it may not be appropriate to use the ITO transparent electrode in electronic devices (reference documents: Bae, S.; Kim, H. K.; Lee, Y.; Xu, X.; Park, J. S.; Zheng, Y.; Balakrishnan, J.; Im, D.; Lei, T.; Song, Y. I.; Kim, Y. J.; Kim, K. S.; Ozyilmaz, B; Ahn, J. H.; Hong, B. H.; Iijima, S, Nat. Nanotechnol. 2010, online).

Further, indium used as a main material is of a very high price and is not easy to process. Thus, an increase of the demand for indium may cause rising cost because of an increase in the price of the raw material.

In this regard, in order to solve the problem of cost rise due to the increase of the price of the raw material for the ITO transparent electrode and the limit in the process, development of other types of transparent electrodes have been actively attempted.

### BRIEF SUMMARY OF THE INVENTION

In view of the foregoing problem, an illustrative embodiment provides a touch panel and a producing method of the same, capable of preventing a graphene electrode from being etched by forming a protection film on the graphene electrode.

However, the problems sought to be solved by the present disclosure are not limited to the above description and other problems can be clearly understood by those skilled in the art from the following description.

In accordance with a first aspect of an illustrative embodiment, there is provided a touch panel comprising a substrate; a graphene electrode formed on the substrate; a protection film formed on the graphene electrode; an insulating film formed on the protection film; and an electrode material formed on the insulating film.

In accordance with a second aspect of the illustrative embodiment, there is provided a producing method for a touch panel, comprising forming a graphene electrode on a substrate; forming a protection film on the graphene electrode; forming a pattern by etching the graphene electrode on which the protection film is formed; forming an insulating film on the pattern; forming a via hole by etching the insulating film; and forming an electrode material on the via hole.

In accordance with the illustrative embodiment, the touch panel uses the graphene film having advantageous electrical, optical and mechanical characteristics as a graphene electrode instead of a conventional ITO electrode. Accordingly, a highly effective touch panel having a competitive price can be provided. Further, since the protection film is formed on the graphene electrode, the graphene electrode can be prevented from being etched when a via hole is formed. Thus, a problem that might be caused when forming the graphene electrode in the touch panel can be avoided.

### BRIEF DESCRIPTION OF THE DRAWINGS

Non-limiting and non-exhaustive embodiments will be described in conjunction with the accompanying drawings. Understanding that these drawings depict only several embodiments in accordance with the disclosure and are, therefore, not to be intended to limit its scope, the disclosure will be described with specificity and detail through use of the accompanying drawings, in which:

FIG. 1 is a cross sectional view of a touch panel in accordance with an illustrative embodiment;

FIG. 2 is a schematic diagram for describing a manufacturing process for a touch panel in accordance with an illustrative embodiment;

FIG. 3 is a schematic diagram for describing a manufacturing process for a touch panel in accordance with an illustrative embodiment;

FIG. 4 is a plan view of the touch panel in accordance with an illustrative embodiment;

FIG. 5 is (a) a cross sectional view of a touch panel in accordance with an example, and (b) a SEM image of a via hole;

FIG. 6 illustrates (a) an image of the via hole in the touch screen panel in accordance with an example after an etching process is performed, and (b) a Raman spectrum measured in the via hole; and

FIG. 7 provides graphs showing graphene electrical conduction characteristics (a) before and (b) after a protection film is coated in the touch panel in accordance with an example.

### DETAILED DESCRIPTION OF THE INVENTION

Hereinafter, illustrative embodiments and examples will be described in detail so that inventive concept may be readily implemented by those skilled in the art.

However, it is to be noted that the present disclosure is not limited to the illustrative embodiments and examples but can be realized in various other ways. In drawings, parts not directly irrelevant to the description are omitted to enhance the clarity of the drawings, and like reference numerals denote like parts through the whole document.

Through the whole document, the terms “connected to” or “coupled to” are used to designate a connection or coupling of one element to another element and include both a case where an element is “directly connected or coupled to” another element and a case where an element is “electronically connected or coupled to” another element via still another element.

Through the whole document, the term “on” that is used to designate a position of one element with respect to another element includes both a case that the one element is adjacent to the another element and a case that any other element exists between these two elements.

Through the whole document, the term “comprises or includes” and/or “comprising or including” used in the document means that one or more other components, steps, operation and/or existence or addition of elements are not excluded in addition to the described components, steps, operation and/or elements unless context dictates otherwise.

The term “about or approximately” or “substantially” are intended to have meanings close to numerical values or ranges specified with an allowable error and intended to prevent accurate or absolute numerical values disclosed for understanding of the present disclosure from being illegally or unfairly used by any unconscionable third party. Through the whole document, the term “step of” does not mean “step for”.

Through the whole document, the term “combination of” included in Markush type description means mixture or combination of one or more components, steps, operations and/or elements selected from the group consisting of components, steps, operation and/or elements described in Markush type and thereby means that the disclosure includes one or more components, steps, operations and/or elements selected from the Markush group.

Through the whole document, the term “A and/or B” means “A, B or A and B.”

In accordance with one aspect of the present disclosure, there is provided a touch panel comprising a substrate; a graphene electrode formed on the substrate; a protection film formed on the graphene electrode; an insulating film formed on the protection film; and an electrode material formed on the insulating film. The touch panel is configured as a monolayer capacitance touch screen panel. Conventionally, an ITO diamond electrode pattern has been formed as a monolayer on a substrate. In accordance with the present disclosure, however, a graphene film is formed on a substrate instead of the ITO electrode. Electrodes are connected in an X-axis of the panel, while electrodes are connected in a Y-axis of the panel after an electrode material is deposited on a via hole formed by etching the insulating film. However, when etching the insulating film to form the via hole, the graphene electrode may also be etched. As a solution, by forming the protection film on the graphene electrode, the graphene electrode can be prevented from being etched when the insulating film is etched.

In accordance with an illustrative embodiment, the substrate may not be particularly limited as long as it is transparent. By way of example, a glass or plastic substrate may be used, but not limited thereto. Further, the substrate may include, but not limited to, a light-transmitting glass material. The substrate may include a light-transmitting flexible polymer material, such as, but not limited to, polyethylene terephthalate (PET), polycarbonate, acryl, cycloolefin and the like.

In accordance with an illustrative embodiment, the protection film may be selected from the group consisting of a photo-curing or thermosetting polymer, an insulating or conductive polymer, a polymer containing an inorganic material, an insulating or conductive inorganic material and combinations thereof, but not limited thereto. By way of example, the polymer containing an inorganic material may be, but not limited to, a F-containing polymer. By way of example, the insulating polymer may be selected from the group consisting of PMMA (Poly Methyl Methacrylate), P4VP (Poly 4-VinylPhenol), SBS (Polystyrene-block-polyisoprene-block-polystyrene), PVC (Polyvinychloride), PP (Polypropylene), ABS (Acrylonitrile Butadiene Styrene), PC (Polycarbonate)/ABS (Acrylonitrile Butadiene Styrene), PE (Polyethylene), PET (Polyethylene Terephthalate), PBT (Polybuthylene Terephthalate), PPS (Polyphenylene Sulfide), PC (Poly cabonate), Nylon, LDPE (Low Density Polyethylene), HDPE (High Density Polyethylene), XLPE (Cross-linked polyethylene), SBR (StyreneButadiene Rubber), BR (Butadiene Rubber), EPR (Ethylene Propylene Rubber), PU (Polyurethane), TEOS (Tetraorthosilicate), and combinations thereof, but not limited thereto. The conductive polymer may be selected from the group consisting of polyaniline, polythiophene, polyethylenedioxythiopene (PEDOT), polystyrenesulfonate (PSS), polypyrrole, polyacetylene, poly(p-phenylene), poly(p-phenylene sulfide), poly(p-phenylene vinylene), polythiophene poly(thienylene vinylene), polyimide, polyacrylate, polyurethane, polyethylene terephthalate, polyether sulfon, polyether ether keton, polycarbonate and combinations thereof, but not limited thereto. The insulating inorganic material may be selected from a group consisting of SiO₂, a-Si (amorphous silicon), SiC, Si₃N₄, LiF, BaF₂, Ta₂O₅, Al₂O₃, MgO, ZrO₂, HfO₂, BaTiO₃, BaZrO₃, Y₂O₃, ZrSiO₄ and combinations thereof, but not limited thereto. The conductive inorganic material may be selected from a group consisting of ITO (Indium Tin Oxide), IZO (Indium Zinc Oxide), ATO (Antimony-doped Tin Oxide), AZO (Al-doped Zinc Oxide), GZO (Gallium-doped Zinc Oxide), IGZO (Indium-Gallium-Zinc Oxide), FTO (Fluorine-doped Tin Oxide), ZnO, TiO₂, SnO₂, WO₃ and combinations thereof, but not limited thereto. The protection film may be formed by a method selected from the group consisting of roll-to-roll coating, bar coating, wire bar coating, spin coating, dip coating, casting, microgravure coating, gravure coating, roll coating, spray coating, screen printing, flexo printing, offset printing, inkjet printing and combinations thereof, but not limited thereto.

In accordance with an illustrative embodiment, the protection film may have a thickness ranging, e.g., from about 1 nm to about 1,000 nm so as not to affect the conductivity of the graphene electrode. By way of example, the thickness of the protection film may range from about 10 to about 1,000 nm, about 20 nm to about 1,000 nm, about 30 nm to about 1,000 nm, about 40 nm to about 1,000 nm, about 50 nm to about 1,000 nm, about 60 nm to about 1,000 nm, about 70 nm to about 1,000 nm, about 80 nm to about 1,000 nm, about 90 nm to about 1,000 nm, about 100 nm to about 1,000 nm, about 200 nm to about 1,000 nm, about 300 nm to about 1,000 nm, about 400 nm to about 1,000 nm, about 1 nm to about 900 nm, about 1 nm to about 800 nm, about 1 nm to about 700 nm, about 1 nm to about 600 nm, about 1 nm to about 500 nm, about 1 nm to about 400 nm, about 1 nm to about 300 nm, about 1 nm to about 200 nm or about 1 nm to about 100 nm, but not limited thereto.

In accordance with an illustrative embodiment, the insulating film may include, but not limited to, SiO₂, Al₂O₃, SiNx, ZrO, TiO₂, a polymer or a photo-curing polymer. As the photo-curing polymer, any of photoresist based polymer that can be cured by ultraviolet ray or infrared ray may be used. By way of example, SU8 may be used, but not limited thereto. The insulating film may have a thickness ranging from, e.g., about 10 nm to about 1,000 nm. By way of example, the thickness of the insulating film may range from about 50 nm to about 1,000 nm, about 100 nm to about 1,000 nm, about 200 nm to about 1,000 nm, about 300 nm to about 1,000 nm, about 400 nm to about 1,000 nm, about 500 nm to about 1,000 nm, about 10 nm to about 900 nm, about 10 nm to about 800 nm, about 10 nm to about 700 nm, about 10 nm to about 600 nm, about 10 nm to about 500 nm, about 10 nm to about 400 nm, about 10 nm to about 300 nm, about 10 nm to about 200 nm or about 10 nm to about 100 nm, but not limited thereto.

In accordance with an illustrative embodiment, the electrode material may include, but not limited to, a metal, graphene or a conductive polymer. By way of example, the electrode material may include a metal selected from the group consisting of Al, Au, Mo, Ag, Cu and combinations thereof, but not limited thereto. By way of example, the electrode material may be selected from the group consisting of polyaniline, polythiophene, polyethylenedioxythiopene (PEDOT), polystyrenesulfonate (PSS), polypyrrole, polyacetylene, poly(p-phenylene), poly(p-phenylene sulfide), poly(p-phenylene vinylene), polythiophene poly(thienylene vinylene), polyimide, polyacrylate, polyurethane, polyethylene terephthalate, polyether sulfon, polyether ether keton, polycarbonate and combinations thereof, but not limited thereto. By way of example, the electrode material may include a PEDOT conductive polymer, but not limited thereto.

In accordance with an illustrative embodiment, the touch panel may have an electrode pattern of a diamond shape, a rectangular shape, a linear shape, a circular shape or a wave shape, but not limited thereto.

In accordance with a second aspect of the present disclosure, there is provided a producing method for a touch panel, comprising forming a graphene electrode on a substrate; forming a protection film on the graphene electrode; forming a pattern by etching the graphene electrode on which the protection film is formed; forming an insulating film on the pattern; forming a via hole by etching the insulating film; and forming an electrode material on the via hole. The touch panel is configured as a monolayer capacitance touch screen panel. Conventionally, an ITO diamond electrode pattern has been formed as a monolayer on a substrate. In accordance with the present disclosure, however, a graphene film is formed on a substrate instead of an ITO electrode. Electrodes are connected in an X-axis of the panel, while electrodes are connected in a Y-axis of the panel after an electrode material is deposited on a via hole formed by etching the insulating film. However, when etching the insulating film to form the via hole, the graphene electrode may also be etched. As a solution, by forming the protection film on the graphene electrode, the graphene electrode can be prevented from being etched when the insulating film is etched.

In accordance with an illustrative embodiment, the substrate may not be particularly limited as long as it is transparent. By way of example, a glass or plastic substrate may be used, but not limited thereto. Further, the substrate may include, but not limited to, a light-transmitting glass material. The substrate may include a light-transmitting flexible polymer material, such as, but not limited to, polyethylene terephthalate (PET), polycarbonate, acryl, cycloolefin, and the like.

In accordance with an illustrative embodiment, graphene used to form the graphene electrode may be manufactured by methods that are typically used for graphene growth in the art, without particularly limited. By way of non-limiting example, chemical vapor deposition may be employed, but not limited thereto. The chemical vapor deposition may include, but not limited to, a rapid thermal chemical vapor deposition (RTCVD), an inductively coupled plasma-chemical vapor deposition (ICP-CVD), a low pressure chemical vapor deposition (LPCVD), an atmospheric pressure chemical vapor deposition (APCVD), a metal organic chemical vapor deposition (MOCVD) and plasma enhanced chemical vapor deposition (PECVD).

In accordance with the illustrative embodiments, the graphene may grow on a graphene growth supporting foil containing a transition metal catalyst by chemical vapor deposition. The graphene may grow on the graphene growth supporting foil containing the transition metal catalyst by providing the graphene growth supporting foil with a carbon source and heat. The transition metal catalyst may include at least one selected from the group consisting of Ni, Co, Fe, Pt, Au, Al, Cr, Cu, Mg, Mn, Rh, Si, Ta, Ti, W, U, V, Zr and stainless steel, but not limited thereto. The carbon source may be, but not limited to, ethane, ethylene, ethanol, acetylene, propane, butane, butadiene, pentane, pentene, cyclopentadiene, hexane, cyclohexane, benzene, toluene, or the like. While supplying such carbon source in the form of vapor, the carbon source may be heat-treated at a temperature ranging from, e.g., about 300° C. to about 2,000° C. whereby carbon components in the carbon source may be combined, forming a hexagonal planar structure. As a result, graphene is formed.

In accordance with the illustrative embodiments, an etching solution may be used to selectively etch the graphene growth supporting foil layer containing the transition metal catalyst. By way of example, the etching solution may be, but not limited to, HF, BOE, Fe(NO₃)₃, (NH₄)₂S₂O₈, or iron chloride (Iron(III) Chloride, FeCl₃).

The graphene may grow at the atmospheric pressure, at a low pressure or in a vacuum, but not limited thereto. By way of non-limiting example, when performing the graphene formation under a atmospheric pressure condition, by using helium (He) or the like as a carrier gas, damage of graphene that might be caused by collision with heavy argon (Ar) at high temperature may be minimized. Further, when performing the graphene formation under the atmospheric pressure condition, the graphene can be simply manufactured at low cost. Meanwhile, when performing the graphene formation at a low pressure or in a vacuum condition, hydrogen (H₂) may be used as an atmosphere gas, and by performing the treatment while raising the temperature, an oxidized surface of the metal catalyst may be reduced. As a result, high-quality graphene can be synthesized.

The graphene formed by the aforementioned method may have a large area having a transversal and/or longitudinal length ranging from, e.g., about 1 mm to about 1,000 m. The graphene may have a uniform quality structure substantially without a defect. Further, the graphene formed by the aforementioned method may include a monolayer or multiplayer of graphene, and electrical characteristics of the graphene may change depending on the thickness thereof. By way of non-limiting example, the thickness of the graphene may be in the range of, e.g., a single layer to about 100 layers.

The graphene may be formed on a substrate and transferred to a substrate of a touch panel of the present disclosure. Alternatively, the graphene electrode may be formed by attaching or wrapping, on the substrate of the touch panel of the present disclosure, the substrate on which the graphene is formed. The shape of the substrate for the graphene may not be particularly limited. By way of example, the substrate may be in the form of, e.g., a foil, a wire, a plate, a tube or a net.

In accordance with an illustrative embodiment, the protection film may be selected from the group consisting of a photo-curing or thermosetting polymer, an insulating or conductive polymer, a polymer containing an inorganic material, an insulating or conductive inorganic material and combinations thereof, but not limited thereto. By way of example, the polymer containing an inorganic material may be, but not limited to, a F-containing polymer. By way of example, the insulating polymer may be selected from the group consisting of PMMA (Poly Methyl Methacrylate), P4VP (Poly 4-VinylPhenol), SBS (Polystyrene-block-polyisoprene-block-polystyrene), PVC (Polyvinychloride), PP (Polypropylene), ABS (Acrylonitrile Butadiene Styrene), PC (Polycarbonate)/ABS (Acrylonitrile Butadiene Styrene), PE (Polyethylene), PET (Polyethylene Terephthalate), PBT (Polybuthylene Terephthalate), PPS (Polyphenylene Sulfide), PC (Poly cabonate), Nylon, LDPE (Low Density Polyethylene), HDPE (High Density Polyethylene), XLPE (Cross-linked polyethylene), SBR(StyreneButadiene Rubber), BR (Butadiene Rubber), EPR (Ethylene Propylene Rubber), PU (Polyurethane), TEOS (Tetraorthosilicate) and combinations thereof, but not limited thereto. The conductive polymer may be selected from the group consisting of polyaniline, polythiophene, polyethylenedioxythiopene (PEDOT), polystyrenesulfonate (PSS), polypyrrole, polyacetylene, poly(p-phenylene), poly(p-phenylene sulfide), poly(p-phenylene vinylene), polythiophene poly(thienylene vinylene), polyimide, polyacrylate, polyurethane, polyethylene terephthalate, polyether sulfon, polyether ether keton, polycarbonate and combinations thereof, but not limited thereto. The insulating inorganic material may be selected from the group consisting of SiO₂, a-Si (amorphous silicon), SiC, Si₃N₄, LiF, BaF₂, Ta₂O₅, Al₂O₃, MgO, ZrO₂, HfO₂, BaTiO₃, BaZrO₃, Y₂O₃, ZrSiO₄ and combinations thereof, but not limited thereto. The conductive inorganic material may be selected from the group consisting of ITO (Indium Tin Oxide), IZO (Indium Zinc Oxide), ATO (Antimony-doped Tin Oxide), AZO (Al-doped Zinc Oxide), GZO (Gallium-doped Zinc Oxide), IGZO (Indium-Gallium-Zinc Oxide), FTO (Fluorine-doped Tin Oxide), ZnO, TiO₂, SnO₂, WO₃ and combinations thereof, but not limited thereto. The protection film may be formed by a method selected from the group consisting of roll-to-roll coating, bar coating, wire bar coating, spin coating, dip coating, casting, microgravure coating, gravure coating, roll coating, spray coating, screen printing, flexo printing, offset printing, inkjet printing and combinations thereof, but not limited thereto.

In accordance with an illustrative embodiment, the protection film may have a thickness ranging, e.g., from about 1 nm to about 1,000 nm so as not to affect the conductivity of the graphene electrode. By way of example, the thickness of the protection film may range from about 10 to about 1,000 nm, about 20 nm to about 1,000 nm, about 30 nm to about 1,000 nm, about 40 nm to about 1,000 nm, about 50 nm to about 1,000 nm, about 60 nm to about 1,000 nm, about 70 nm to about 1,000 nm, about 80 nm to about 1,000 nm, about 90 nm to about 1,000 nm, about 100 nm to about 1,000 nm, about 200 nm to about 1,000 nm, about 300 nm to about 1,000 nm, about 400 nm to about 1,000 nm, about 1 nm to about 900 nm, about 1 nm to about 800 nm, about 1 nm to about 700 nm, about 1 nm to about 600 nm, about 1 nm to about 500 nm, about 1 nm to about 400 nm, about 1 nm to about 300 nm, about 1 nm to about 200 nm or about 1 nm to about 100 nm, but not limited thereto.

In accordance with an illustrative embodiment, the insulating film may include, but not limited to, SiO₂, Al₂O₃, SiNx, ZrO, TiO₂, a polymer or a photo-curing polymer. As the photo-curing polymer, any of photoresist based polymer that can be cured by ultraviolet ray or infrared ray may be used. By way of example, SU8 may be used, but not limited thereto. The insulating film may have a thickness ranging from, e.g., about 10 nm to about 1,000 nm. By way of example, the thickness of the insulating film may range from about 50 nm to about 1,000 nm, about 100 nm to about 1,000 nm, about 200 nm to about 1,000 nm, about 300 nm to about 1,000 nm, about 400 nm to about 1,000 nm, about 500 nm to about 1,000 nm, about 10 nm to about 900 nm, about 10 nm to about 800 nm, about 10 nm to about 700 nm, about 10 nm to about 600 nm, about 10 nm to about 500 nm, about 10 nm to about 400 nm, about 10 nm to about 300 nm, about 10 nm to about 200 nm or about 10 nm to about 100 nm, but not limited thereto.

In accordance with an illustrative embodiment, the electrode material may include, but not limited to, a metal, a graphene or a PEDOT conductive polymer. By way of example, the electrode material may include a metal selected from the group consisting of Al, Au, Mo, Ag, Cu and combinations thereof, but not limited thereto. By way of example, the electrode material may be selected from the group consisting of polyaniline, polythiophene, polyethylenedioxythiopene (PEDOT), polystyrenesulfonate (PSS), polypyrrole, polyacetylene, poly(p-phenylene), poly(p-phenylene sulfide), poly(p-phenylene vinylene), polythiophene poly(thienylene vinylene), polyimide, polyacrylate, polyurethane, polyethylene terephthalate, polyether sulfon, polyether ether keton, polycarbonate and combinations thereof, but not limited thereto. By way of example, the electrode material may include a PEDOT conductive polymer, but not limited thereto.

In accordance with an illustrative embodiment, the touch panel may have an electrode pattern of a diamond shape, a rectangular shape, a linear shape, a circular shape or a wave shape, but not limited thereto.

In accordance with an illustrative embodiment, in the process of forming the via hole, the graphene electrode may not be etched due to the presence of the protection film, but not limited thereto.

In accordance with an illustrative embodiment, the pattern may be formed by etching with plasma of oxygen, CF₄, CHF₃, NF₃, CCl₄, CCl₂F₂, C₃F₈, C₂F₆, or the like, but not limited thereto.

In accordance with an illustrative embodiment, the via hole may be formed by dry etching or photolithography, but not limited thereto. By way of example, the via hole may be formed by etching an insulating film by an etching gas of SF₆, CF₄, or the like.

Below, non-limiting and non-exhaustive illustrative embodiments and examples of the touch panel and the producing method of the same in accordance with the present disclosure will be discussed in detail.

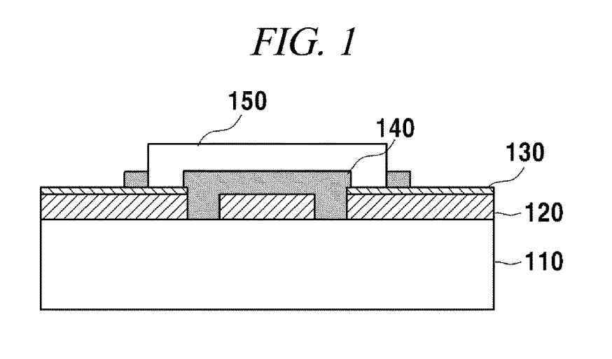

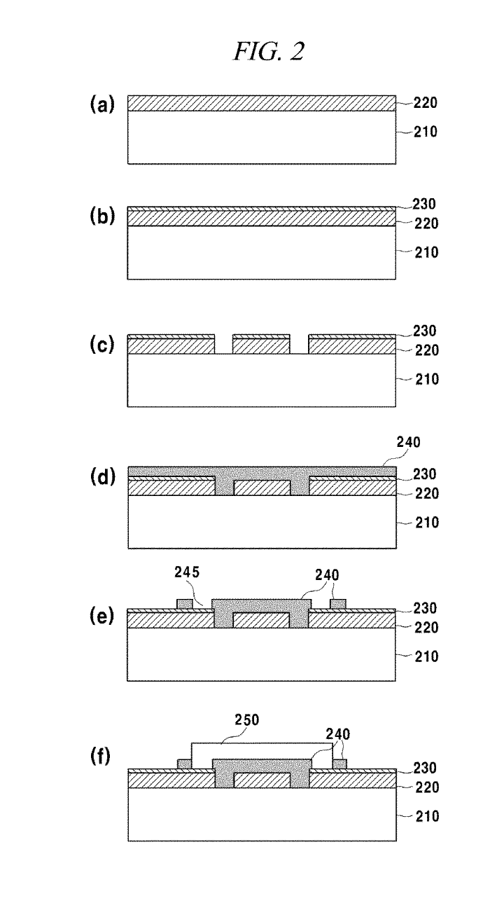

FIG. 1 is a cross sectional view illustrating a touch panel in accordance with an illustrative embodiment, and FIG. 2 is a schematic diagram for describing a manufacturing process for a touch panel in accordance with the illustrative embodiment.

As shown in FIG. 1, the touch panel in accordance with an illustrative embodiment may include, on a substrate 110, a graphene electrode 120, a protection film 130, an insulating film 140 and an electrode material 150. As depicted in FIG. 2, the manufacturing process for a touch panel may include the steps of forming a graphene electrode 220 on a substrate 210; forming a protection film 230 on the graphene electrode 220; forming a pattern by etching the graphene electrode 220 on which a protection film 230 is formed; forming an insulating film 240 on the pattern; and forming a via hole 245 by etching the insulating film 240; and forming the electrode material 250 on the via hole 245. Electrodes are connected in an X-axis of the panel, while electrodes are connected in a Y-axis of the panel after the electrode material is deposited on and connected on the via hole formed by etching the insulating film. The graphene electrodes 120 are arranged in the direction of the X-axis and electrically connected to a connector (not shown) via conducting wires (not shown).

In accordance with an illustrative embodiment, the substrate may not be particularly limited as long as it is transparent. By way of example, a glass or plastic substrate may be used, but not limited thereto. Further, the substrate may include, but not limited to, a light-transmitting glass material. The substrate may include a light-transmitting flexible polymer material, such as, but not limited to, polyethylene terephthalate (PET), polycarbonate, acryl, cycloolefin, and the like.

In accordance with an illustrative embodiment, the graphene electrode 220 may be formed by sputtering or chemical vapor deposition. By way of example, the graphene may grow on the substrate 210 by chemical vapor deposition by providing a metal catalyst layer for graphene growth with a carbon source and heat, but not limited thereto. In accordance with an illustrative embodiment, the protection film 230 may be formed on the graphene electrode 220 to protect the graphene electrode 220 from being etched when the insulating film 240 is etched to form the via hole 245. The protection film 230 may be selected from the group consisting of a photo-curing or thermosetting polymer, an insulating or conductive polymer, a polymer containing an inorganic material, an insulating or conductive inorganic material and combinations thereof, but not limited thereto. The protection film 230 may have a thickness ranging from, e.g., about 1 nm to about 1,000 nm so as not to affect the conductivity of the graphene electrode.

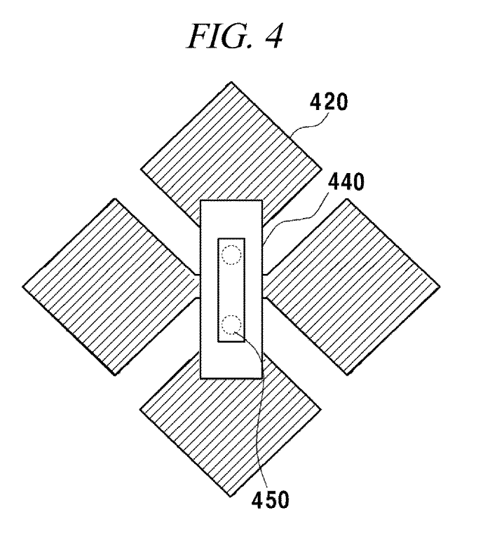

In accordance with an illustrative embodiment, the graphene electrode 220 on which the protection film 230 is formed may be etched to form a diamond electrode pattern, but not limited thereto. For the etching of the graphene electrode 220, any of etching method used in the art may be used without being particularly limited. By way of non-limiting example, oxygen plasma etching method may be used, but not limited thereto. FIG. 4 is a plan view of a touch panel in accordance with an illustrative embodiment. A graphene electrode on which a protection film is formed may be formed as a monolayer diamond pattern 420, thus forming a monolayer capacitance touch screen panel, but not limited thereto.

In accordance with an illustrative embodiment, after forming the insulating film 240 on the pattern, the via hole 245 may be formed by performing etching using an etching gas. The insulating film may include, but not limited to, SiO₂, Al₂O₃, SiNx, ZrO, TiO₂, a polymer or a photo-curing polymer. As the photo-curing polymer, any of photoresist based polymer that can be cured by ultraviolet ray or infrared ray may be used. By way of example, SU8 may be used, but not limited thereto.

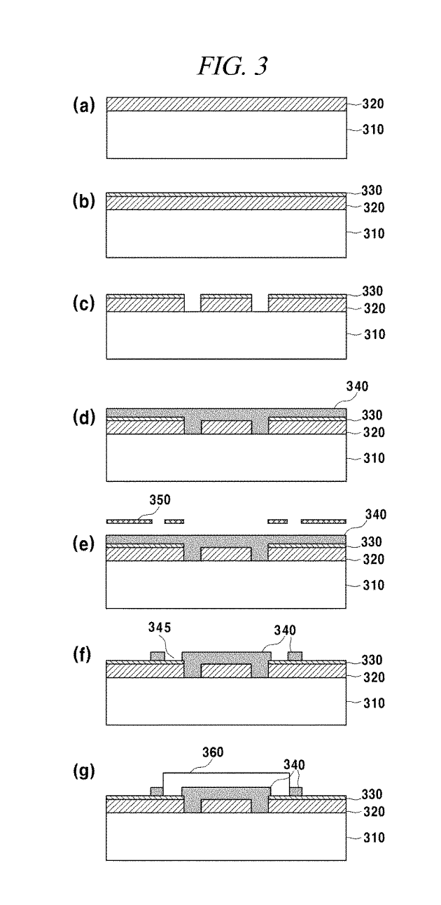

FIG. 3 is a schematic diagram for describing a process of manufacturing a touch panel by using a photo-curing polymer as an insulating film. After forming a graphene electrode 320 on a substrate 310, a protection film 330 is formed on the graphene electrode 320. Then, by etching the graphene electrode 320 on which the protection film 330 is formed, a pattern is formed. An insulating film 340 is formed on the pattern. Thereafter, a photo mask 350 is placed above the insulating film 340, and the insulating film 340 is exposed to an ultraviolet ray or an infrared ray irradiated thereto. Then, the exposed insulating film is developed, so that a via hole 345 is formed. In this way, when using the photo-curing polymer as the insulating film, the process of forming the insulating pattern and the etching process can be simplified.

The insulating film may have a thickness ranging from, e.g., about 10 nm to about 1,000 nm. By way of example, the thickness of the insulating film may range from about 50 nm to about 1,000 nm, about 100 nm to about 1,000 nm, about 200 nm to about 1,000 nm, about 300 nm to about 1,000 nm, about 400 nm to about 1,000 nm, about 500 nm to about 1,000 nm, about 10 nm to about 900 nm, about 10 nm to about 800 nm, about 10 nm to about 700 nm, about 10 nm to about 600 nm, about 10 nm to about 500 nm, about 10 nm to about 400 nm, about 10 nm to about 300 nm, about 10 nm to about 200 nm or about 10 nm to about 100 nm, but not limited thereto. The etching gas may include, but not limited to, SF₆, CF₄, or the like. By way of example, the via hole may be formed by drying etching or photolithography.

In accordance with an illustrative embodiment, as the electrode material 250 is deposited on the insulating film 240 and the via hole 245, electrodes of a Y-axis pattern of the touch panel is connected. The electrode material 250 may include, but not limited to, Al or Au.

Now, non-limiting example of the present disclosure will be described.

### EXAMPLES

### Experiment Example 1

After depositing a graphene electrode on a Si/SiO₂ substrate, a P4PV polymer was coated on the graphene electrode as a protection film. The graphene electrode coated with the P4VP polymer protection film was etched into a diamond pattern by using an oxygen plasma etching method. Then, SiO₂ was formed on the pattern as an insulating film. Thereafter, the SiO₂ insulating film was dry-etched, so that a via hole is formed.

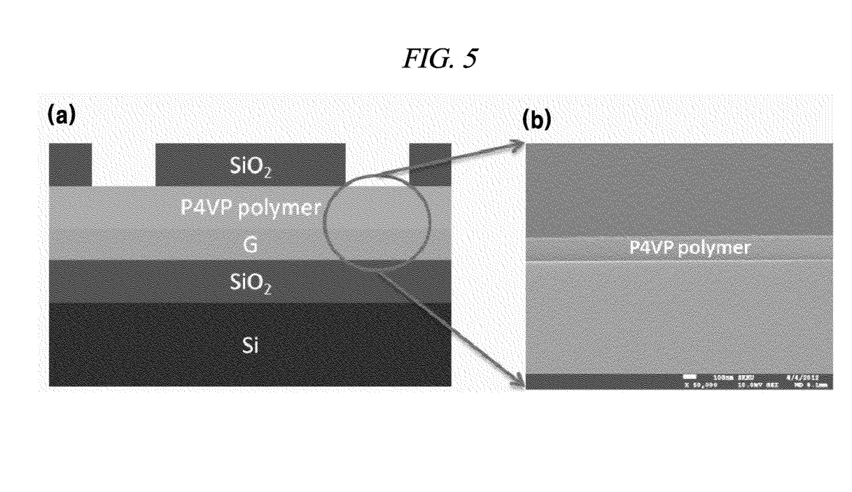

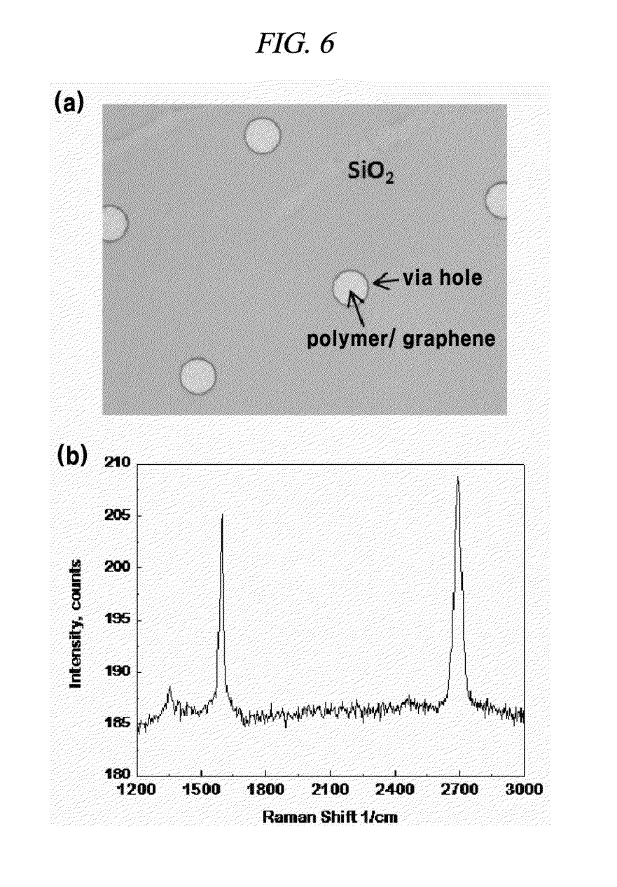

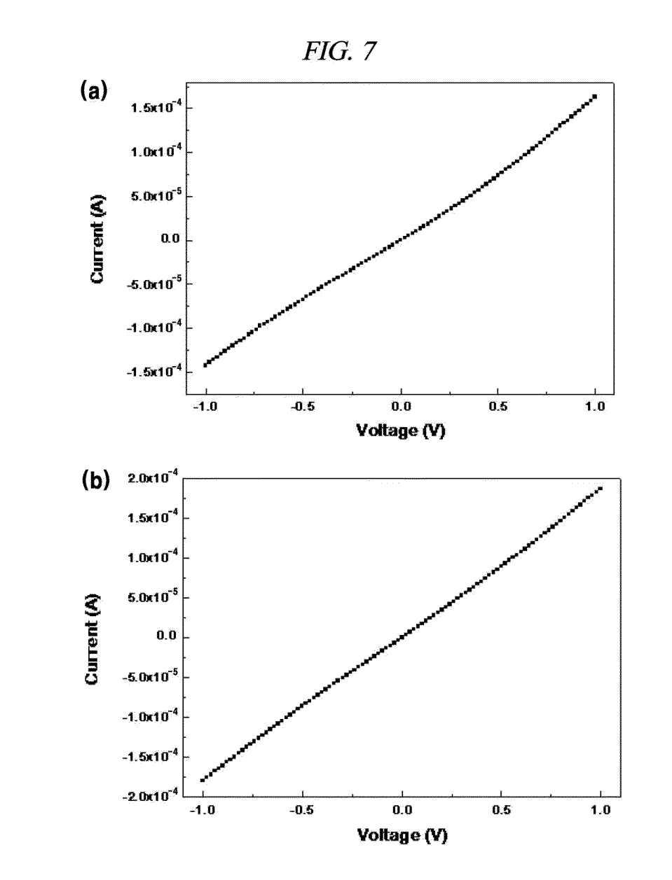

FIG. 5 is (a) a cross sectional view of a touch screen panel in accordance with an example, and (b) a SEM image of a via hole. FIG. 6 illustrates (a) an image of the via hole in the touch screen panel after the etching process is performed, and (b) a Raman spectrum measured in the via hole. As can be seen from the Raman spectrum, a typical graphene characteristic is exhibited. FIG. 7 provides graphs showing graphene electrical conduction characteristics (a) before and (b) after the protection film is coated. Before and after the protection film is coated, similar conduction characteristics are exhibited, which implies that the graphene electrode is not etched due to the presence of the polymer protection film when the via hole is etched.

The above description of the illustrative embodiments is provided for the purpose of illustration, and it would be understood by those skilled in the art that various changes and modifications may be made without changing technical conception and essential features of the illustrative embodiments. Thus, it is clear that the above-described illustrative embodiments are illustrative in all aspects and do not limit the present disclosure. For example, each component described to be of a single type can be implemented in a distributed manner. Likewise, components described to be distributed can be implemented in a combined manner.

The scope of the inventive concept is defined by the following claims and their equivalents rather than by the detailed description of the illustrative embodiments. It shall be understood that all modifications and embodiments conceived from the meaning and scope of the claims and their equivalents are included in the scope of the inventive concept.

### EXPLANATION OF CODES

110, 210, 310: substrate
120, 220, 320: graphene electrode
130, 230, 330: protection film
140, 240, 340, 440: insulating film
245, 345, 450: via hole
150, 250, 360: electrode material
420: diamond pattern

What is claimed is:

1. A touch panel comprising:
a substrate;
a graphene electrode formed on the substrate;
a protection film formed on the graphene electrode;
an insulating film formed on the protection film; and
an electrode material formed on the insulating film.

2. The touch panel of claim 1,
wherein the protection film is selected from the group consisting of a photo-curing or thermosetting polymer, an insulating or conductive polymer, a polymer containing an inorganic material, an insulating or conductive inorganic material and combinations thereof.

3. The touch panel of claim 1,
wherein the protection film has a thickness ranging from about 1 nm to about 1,000 nm.

4. The touch panel of claim 1,
wherein the insulating film includes SiO₂, Al₂O₃, SiNx, ZrO, TiO₂, or a polymer.

5. The touch panel of claim 1,
wherein the electrode material includes a metal, a graphene or a PEDOT (polyethylenedioxythiopene) conductive polymer.

6. The touch panel of claim 1,
wherein the touch panel includes an electrode pattern of a diamond shape, a quadrangular shape, a linear shape, a circular shape or a wave shape.

7. A producing method for a touch panel, comprising:
forming a graphene electrode on a substrate;
forming a protection film on the graphene electrode;
forming a pattern by etching the graphene electrode on which the protection film is formed;
forming an insulating film on the pattern;
forming a via hole by etching the insulating film; and
forming an electrode material on the via hole.

8. The producing method of claim 7,
wherein the protection film is selected from the group consisting of a photo-curing or thermosetting polymer, an insulating or conductive polymer, a polymer containing an inorganic material, an insulating or conductive inorganic material and combinations thereof.

9. The producing method of claim 7,
wherein the protection film has a thickness ranging from about 1 nm to about 1,000 nm.

10. The producing method of claim 7,
wherein the insulating film includes SiO₂, Al₂O₃, SiNx, ZrO, TiO₂, or a polymer.

11. The producing method of claim 7,
wherein the electrode material includes a metal, graphene or a PEDOT (polyethylenedioxythiopene) conductive polymer.

12. The producing method of claim 7,
wherein the touch panel includes an electrode pattern of a diamond shape, a quadrangular shape, a linear shape, a circular shape or a wave shape.

13. The producing method of claim 7,
wherein the graphene electrode is not etched by the protection film in the process of forming the via hole.

14. The producing method of claim 7,
wherein the pattern is formed by performing etching using plasma of oxygen, CF₄, CHF₃, NF₃, CCl₄, CCl₂F₂, C₃F₈, or C₂F₆.

15. The producing method of claim 7,
wherein the via hole is formed by dry etching or photolithography.
